(19) United States
(12) Patent Application Publication
(10) Pub. No.: US 2005/0136826 A1
(43) Pub. Date: Jun. 23, 2005

(54) Central processing unit cooling device

(76) Inventor: Liang-Hua Wang, Taipei (TW)

Correspondence Address: Liang-Hua Wang, 123,SEC.2, Hwanher West Road, YENG HER, TAIPEI HSIEN, TW

(21) Appl. No.: 10/741,940

(22) Filed: Dec. 22, 2003

(51) Int. Cl. H05K 7/20

(52) U.S. Cl. 454/184; 361/695

(57) ABSTRACT

The system is combined with an inlet and an outlet air vent. Within the inlet air vent, there is a cooling fan attached. Also there is a half-circled shape net piece designed in the air ventilation system that has numerous holes on the net piece. By using the half-circled shape net piece, it will create a greater contact of hot and cold air with the central processing unit. The cooling fan will create the air circulation passing through the central processing unit.

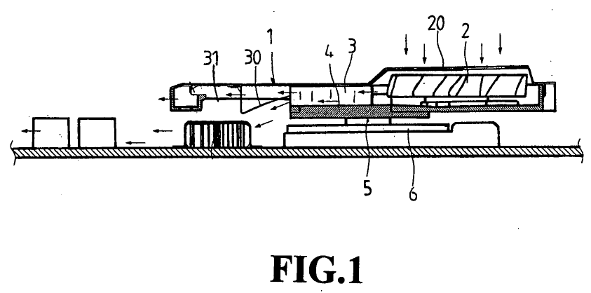

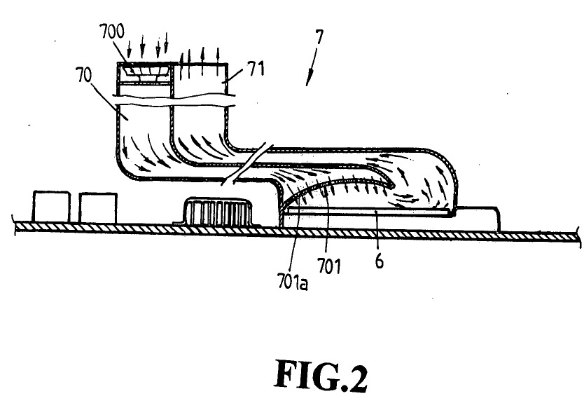

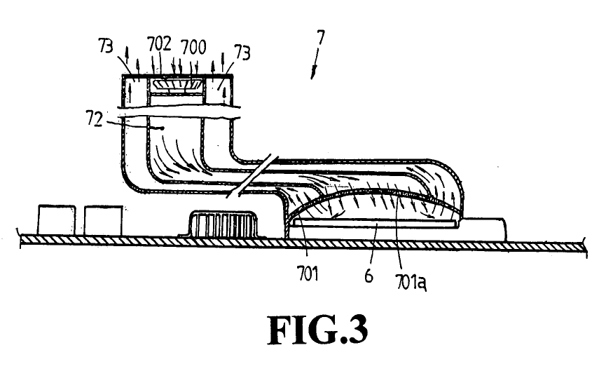

### FIELD OF THE INVENTION

The present invention relates to the field of technology pertaining to a device for cooling/circulating the heat created by the Central Processing Unit.

### BACKGROUND OF THE INVENTION

I, the inventor, have designed a device that circulates the heat created by the Central processing unit. The device has a remarkable result for circulating the heat away from the Central processing Unit. The materials used to make the device are heat and electric insulated. It will circulate the heat from the Central Processing Unit to the outside of the computer. Thus, it will have a remarkable result of circulating the heat away from the Central Processing Unit and cooling it down.

Past Technology:

In the past decade, the computer technology has improved tremendously. As the computer technology companies design Central Processing Units faster and faster, the Central Processing Unit will create a greater amount of heat because of the increase of speed of pulse that the Central Processing Unit can send.

As the temperature of the Central Processing Unit increase, it will also increase a greater chance for the computer to freeze and damage other hard wares within the computer. Thus it is necessary to apply a cooling system that can either circulate the heat away from the computer or cool the Central Processing Unit down to a satisfying temperature for it to maximize its functions.

Present Cooling System:

A typical central processing unit has a cooling system attached above. In diagram 1 is a typical cooling system. On the right within the hard case, there is a cooling fan (2). On the top of the cooling fan (2), there is an outlet for air (20). Next to the cooling fan (2), there is a cooling fin piece (3). The bottom of a circulation tube (30) and an air circulation outlet (31), there is a heat conduction block (4). Underneath the heat conduction block (4), there is a heat conduction film (5). The heat conduction film (5) is attached to the central processing unit (6). The heat from created by the central processing unit (6) will transfer through the conduction film (5) and into the heat conduction block (4). Then by using the cooling fan (2) to circulate the heat away from the central processing unit (6); through the circulation tube (30) and transfer out at the circulation outlet (31). The heat will be blown to the hard wares near the central processing unit (6).

Summary/Comparison:

Present cooling system, a typical Central Processing Unit has other electronic hard wares that also create heat. Which makes it difficult to circulate the heat from the Central Processing Unit directly away. Thus, the present cooling system blows the heat directly away from the Central Processing Unit and onto other electronic hard wares.

Thus the cooling system, Central Processing Unit and the electronic hard wares are all directly connected. So the heat that is blown away from the Central Processing Unit will eventually circulate back to the origin, the Central Processing Unit. Therefore, the functions of the present cooling system are limited.

The Central Processing Unit cooling device is a kind of convection system that is specially designed for the central processing unit. The main purpose is applying an air ventilation system on the central processing unit that is isolated to the outside of the hardware within the computer. The materials that are used to make the air ventilation system are heat and electric insulated.

The system is combined with an inlet and an outlet air vent. Within the inlet air vent, there is a cooling fan attached. Also there is a half-circled shape net piece designed in the air ventilation system that has numerous holes on the net piece. By using the half-circled shape net piece, it will create a greater contact of hot and cold air with the central processing unit. The cooling fan will create the air circulation passing through the central processing unit.

Afterwards, using the output air vent, the hot air will be circulated to the outside of the computer. With the one inlet and outlet air circulation design, it will have a strong effect of circulating the heat from the central processing unit away. Thus, it can maximize the purpose of circulating the heat from the central processing unit away.

### BRIEF DESCRIPTION OF THE DRAWINGS

Diagram 1 is a front lavational view of a typical cooling system for the Central Processing Unit.

Diagram 2 is a front lavational view of the first cooling system for the Central Processing Unit designed by the inventor.

Diagram 3 is a front lavational view of the second cooling system for the Central Processing Unit designed by the inventor.

### DETAILED DESCRIPTION OF THE PREFERRED EMBODIMENTS

In diagram 2, I, the inventor, want to provide a kind specializing cooling ventilation system for the central processing unit. It is mainly applying an air ventilation system (7) on the Central Processing Unit (6). The air ventilation system (7) is purposely made with materials that isolate from the other hard wares in the computer. Materials that are heat and electric insulated also make it. The air ventilation system (7) is combined with an inlet air vent (71) and outlet air vent (71). Within the input air vent (70), there is a cooling fan (700) attached. Also there is a half-circled shape net piece (701) closely placed on the Central Processing Unit (6). The half-circled shape net piece (701) has numerous holes (701a). By using the half-circled shape net piece (701), it will create a greater contact of hot and cold air with the Central Processing Unit (6). The cooling fan (700) will create air circulation through the numerous holes (701a) in the half-circled shape net piece (701) and the Central Processing Unit (6). Afterwards, using the outlet air vent (71), the hot air will be circulated to the outside of the computer.

Besides the design, diagram 2, there is another design using an interior air vent (72) and the exterior air vent (73). The air vent (7) is separated into two sections interior air vent (72) and exterior air vent (73). Using the half-circled shape net piece (701) and the intersection net piece (702). The interior air vent (72) and the exterior air vent (73) are connected as one. The cooling fan (70) can be applied at the (72) inlet air vent or the (73) outlet air vent. Using the cooling fan (70), it will create an air circulation through the numerous holes (701a) of the half-circled shaped net piece (701) blowing at the Central Processing Unit (6). Afterwards using either exterior air vent (73) or the inlet air vent (72) to transport the hot air out to the exterior of the computer.

1. A special kind of cooling system for the central processing unit is mainly applying an air ventilation system on the central processing unit, which the air ventilation system is isolated from the other hard wares within the computer. The materials that are heat and electric insulated make the air ventilation system. The system is combined with an inlet and outlet air vent. Within the input air vent, there is a cooling fan attached. Also there is a half-circled shape net piece closed placed on the central processing unit. The half-circled shape net piece is designed with numerous holes. By using the half-circled shape net piece, it will create a greater contact of hot and cold air with the central processing unit. The cooling fan will create the air circulation passing through the central processing unit. Afterwards, using the outlet air vent, the hot air will be circulated to the outside of the computer. With the one inlet and outlet air circulation design, it will have a strong effect of circulating the heat from the central processing unit away. Thus, it will maximize the purpose of circulating the heat from the central processing unit away.

2. The inlet air vent and the outlet air vent can be changed as interior air vent and exterior air vent. The cooling fan can be applied at either, the interior air vent or the exterior air vent. Then using the cooling fan, it will create an air circulation through the numerous holes of the half-circled shaped net piece blowing at the Central Processing Unit. Afterwards using either exterior air vent or the inlet air vent to transport the hot air out to the exterior of the computer.
